(19) United States
(12) Patent Application Publication
(10) Pub. No.: US 2024/0057482 A1
(43) Pub. Date: Feb. 15, 2024

(54) METHOD AND ARRANGEMENT FOR JOINING A PIEZOELECTRIC MATERIAL FOR A WIDE TEMPERATURE RANGE

(71) Applicant: Flexim Flexible Industriemesstechnik GmbH, Berlin (DE)

(72) Inventors: Oleg Shapovalov, Cottbus (DE); Thomas Heckel, Kleinmachnow (DE); Rainer Boehm, Rietz-Neuendorf (DE); Stefan Göbbels, Berlin (DE); Bernhard Funck, Rostock (DE)

(21) Appl. No.: 18/489,586

(22) Filed: Oct. 18, 2023

Related U.S. Application Data
(63) Continuation of application No. PCT/EP2022/059132, filed on Apr. 6, 2022.

(30) Foreign Application Priority Data
Apr. 20, 2021 (DE) 10 2021 109 992.7

(51) Int. Cl. H10N 30/05; H10N 30/071; H10N 30/093; H04R 31/00

(52) U.S. Cl. CPC H10N 30/05; H10N 30/071; H10N 30/093; H04R 31/00; H04R 17/00

(57) ABSTRACT

A joining method is for producing a sound transducer system. The method includes: providing a piezoelectric material and a plurality of components, each of the components being characterized by a solidus temperature; arranging the piezoelectric material and the plurality of components in the form of a stack, so that adjacent to a front face of the piezoelectric material there is a front stack part and adjacent to a rear face of the piezoelectric material there is a rear stack part; and consolidating the stack by the introduction of heat and pressure for a predetermined period of time, none of the solidus temperatures of the plurality of components being exceeded during the consolidation; and, during the consolidation, the piezoelectric material being directly acoustically coupled to an immediately adjacent component of the front and/or rear stack part.

### CROSS-REFERENCE TO RELATED APPLICATIONS

This application is a continuation application of international patent application PCT/EP2022/059132, filed Apr. 6, 2022, designating the United States and claiming priority from German application 10 2021 109 992.7, filed Apr. 20, 2021, and the entire content of both applications is incorporated herein by reference.

### TECHNICAL FIELD

The disclosure relates to the development and production of sound transducer systems, more particularly of an ultrasound transducer system, for sustained high-temperature service, but also relates generally to the joining of a metal and a piezoelectric material.

### BACKGROUND

In the ultrasound measurement of flow or the monitoring of structure condition, conversion of the electrical signals into ultrasound signals and vice versa takes place using sound transducer systems. These sound transducer systems consist of a piezoelectric material for conversion between electrical and acoustic signals, and the leader member for the transmission of sound between the piezoelectric material and the measurement object or test piece. Piezo ceramics or piezo crystals are used as piezoelectric materials. Existing sound transducer systems are suitable on a sustained basis only for service within the comparatively narrow temperature range from −40° to 200° C. The intention presently is to cover a temperature range from −200° C. to 600° C. A temperature range of this kind is characteristic, for example, of applications in the chemical industry, as for example for the ultrasound measurement of flow, or for the monitoring of structure condition. The chemical industry uses the temperature range from −200° C. to 600° C., more particularly the temperature range from −20° C. to 500° C. and the temperature range from −200° C. to 80° C., and the monitoring of structure condition uses the temperature range from −80° C. to 400° C.

For service within such a broad temperature interval, it has to date typically been necessary to operate a number of sound transducer systems in parallel, with the transducer systems utilizing different sensor concepts. Disadvantages arise from this, due in particular to different signal-to-noise ratios in the individual transducers and to the resultant inadequate accuracy of measurement. A combination of different sound transducer systems with overlapping temperature ranges is associated with considerable cost and complexity. Moreover, known sound transducer systems able to cover a relatively broad temperature interval are suitable solely for short-term operation. Systems which only permit short-term operation, however, are unsuited to numerous applications, such as for the ultrasound measurement of flow or for the monitoring of structure condition, for example, as both applications require continuous measurements.

A sound transducer system which can be deployed over a wide temperature range, including in particular under high-temperature conditions to 600° C., moreover, is subject to particular requirements in terms of a sustainedly reliable acoustic coupling of the piezoelectric material. This produces the need for the piezoelectric material to be connected in a force-fitting manner, that is, acoustically and/or electrically, to the two electrodes used to drive the piezoelectric material, and for the piezoelectric material to be connected to the leader member in a similar manner. In a known manner (see below), this is achieved in the prior art via a liquid coupling layer, for example.

One of the biggest challenges in developing an ultrasound test head for sustained extreme-temperature service is the production of the temperature-stable coupling between the piezoelectric material and the leader member, which also serves as electrode. Given that the majority of conventional adhesive materials can be used in general only from around −40° C. to around 150° C., a firm material-to-material connection between the individual components is achievable only via high-temperature-compatible joining techniques.

Similarly, the reliable connection of metal electrodes with a piezoelectric material, as for example in a ceramic filter or an intermediate frequency filter, a ceramic resonator, a piezo actuator, or for a ceramic bushing of a high-temperature sensor, may be exposed to extreme operating temperatures.

A candidate solution for the concerns identified are soldering methods, particularly metal soldering and glass soldering. Nevertheless, each of the stated techniques has its own disadvantages. Because the high-temperature-resistant piezoelectric material to be connected is usually an oxide-based material, the use of conventional metal soldering technology is made significantly more difficult by the typically very poor wetting of the nonmetallic material by the molten metallic solder.

Conversely, glass solder materials have good wetting for nonmetallic materials, but feature a number of other disadvantages, as for instance:

poor electrical conductivity, leading to a reduction in the effective field strength at the piezoelectric material;

a generally relatively low (and in most cases noncorresponding) coefficient of thermal expansion, possibly leading to cracking in the solder layer and in the piezoelectric material;

a brittleness which in the event of a change in temperature leads to cracking in the coupling layer and hence to deterioration in the coupling properties.

All of the stated disadvantages can be resolved through the use of low-melting glass solder materials. In that case, the softening temperature of the solder material is well below the service temperature, and so the glass melt serves as a liquid coupling. By this means it is possible to realize high-temperature applications, but not applications at low temperatures.

Couplings of this kind which are liquid under service conditions, however, have a strong corrosive effect on the part of the glass melt at high temperatures and hence exhibit only inadequate long-term stability, thereby rendering them suitable solely for short-term service.

In contradistinction to this, active soldering is a known technique for metallic connection of oxide materials, with the active solder material including an actively oxidizing component. The connection is made in this case through a chemical reaction, in which at the interface between molten active solder and oxide material, an active layer is formed which connects the oxide material to the solder layer. Implementing the active solder technology for coupling a piezoelectric material in a sound transducer, for example, lithium niobate, to a steel electrode results unfortunately, because of

the use of a protective (gas) atmosphere in the soldering operation and

an unusual oxygen activity on the part of the lithium niobate,

in an excessive physicochemical load both on the piezoelectric material and on the solder material, leading to impaired long-term stability and to adversely affected piezo properties. Similar challenges may affect piezo actuators, as for example high-temperature printheads, and ceramic filters or contact bushings of sensors.

### SUMMARY

Against this background, it is an object of the disclosure to provide a joining method that is adapted for use in sound transducer systems in the measurement scenarios described at the outset, especially over the specified wide temperature range. The joined connection produced by the method enables, on a sustained basis, both a reliable acoustic coupling and a reliable electrical connection between the piezoelectric material of the sound transducer and the coupled electrodes and/or leader members over the entire specified temperature range.

The aforementioned object is, for example, achieved via a joining method for producing a sound transducer system. The method includes: providing a piezoelectric material and a plurality of components, each of the components having a solidus temperature; arranging the piezoelectric material and the plurality of the components in a stack, so that adjacent to a front face of the piezoelectric material there is a front stack part and adjacent to a rear face of the piezoelectric material there is a rear stack part; consolidating the stack using heat and pressure for a predetermined time period, wherein none of the solidus temperatures of the plurality of the components is exceeded; and, during the consolidating, the piezoelectric material being directly acoustically coupled to an immediately adjacent component of at least one of the front and rear stack part.

It proved to be the case, surprisingly, that an active solder foil can be used in a nonconventional manner as a joining material. In contrast to the customary use of an active solder foil in the art, it is employed in the disclosure at a substantially lower temperature than that of the melting point of the solder material. Investigations of the dynamics of formation of the active layer in contact with lithium niobate, which has been presently used illustratively as the piezoelectric material, have shown that even at temperatures below the melting point of the solder material, a mechanically and electrically reliable connection can be produced. Advantageously, the reduced operating temperature proposed in the disclosure makes it possible to prevent melting and subsequent recrystallization of the joining material, and also leads to a reduction in otherwise unavoidable thermal stresses in the curing phase of the joining operation.

The reduced operating temperature proposed in the disclosure allows joining to take place without a protective atmosphere, and this not only lessens the cost and complexity involved in producing the joined connection, but also prevents the negative effect of oxygen reduction, that is, chemical reduction of the piezo crystal through oxygen loss in the low-oxygen protective atmosphere, and the associated loss of the piezoelectric properties of the lithium niobate piezo crystal used (MH Amini, AN Sinclair, TW Coyle (2015) High-temperature ultrasonic transducer for real-time inspection. Physics Procedia 70:343-347).

Subsequently, it was surprisingly found that in accordance with the disclosure, a metal foil may also be employed without addition of the commercially customary active components in the same manner. In this connection, a metal foil refers to a metal rolled to form a foil, such as, for example, an aluminum foil, a silver foil, a titanium foil, a copper foil, et cetera.

According to typical embodiments, the use is proposed of a joining foil as a depot of an active element, according to the embodiment shown in FIG. 1 of a layer arrangement for the joining of a piezoceramic material (crystal or ceramic) and of relevant connection electrodes or of metallic leader members and/or damping members utilized as such. The active element, which is a constituent of the joining foil, forms a so-called active layer under the influence of an elevated temperature and pressure which is active on the joining partners during the joining operation, with a constituent of the piezoelectric material. The active layer, as a separate phase, produces a substance-to-substance connection between the piezoelectric material and the active element depot. An active layer is also formed between the active element depot and a constituent of the attached joining partner, more particularly a metallic leader member or damping member. As a result of the force-fitting and/or substance-to-substance connection, an electrically and/or acoustically (that is, mechanically) conductive connection is produced between two adjacent components, thus allowing the piezoelectric material to be utilized in a sound transducer system.

### BRIEF DESCRIPTION OF DRAWINGS

The invention will now be described with reference to the drawings wherein:

FIG. 1 shows the arrangement of the disclosure for joining the piezoelectric material via joining foils;

FIG. 2 shows the temperature profile over the time period of the joining operation. Here, TSF denotes a melting point of the joining material or its solidus temperature if a melting interval is present;

FIG. 3 shows the growth of the signal amplitude in the course of the joining operation in conjunction with the temperature profile employed;

FIG. 4 shows a metallographic picture of the joining layer produced;

FIG. 5 shows the profile of the signal amplitude and of the temperature in the course of the joining operation with a joining foil composed of a silver-base alloy and with the piezoelectric material lithium niobate;

FIG. 6 shows the profile of the signal amplitude and of the temperature in the course of the joining operation with a joining foil composed of silver and with the piezoelectric material lithium niobate; and,

FIG. 7 shows the profile of the signal amplitude and of the temperature in the course of the joining operation with a joining foil composed of silver and with the piezoelectric material bismuth titanate.

### DETAILED DECRIPTION

An embodiment proposes a joining method for producing a sound transducer system for extreme-temperature service from −200° C. to 600° C., more particularly from −20° C. to 500° C., from −200° C. to 80° C. and from −80° C. to 400° C., which includes the following steps:

providing a piezoelectric material 3 and a plurality of components, each of the components being characterized by a solidus temperature;

arranging the piezoelectric material 3 and the plurality of the components in the form of a stack 10, so that adjacent to a front face of the piezoelectric material 3 there is a front stack part and adjacent to a rear face of the piezoelectric material 3 there is a rear stack part; and

consolidating the stack 10 with introduction of heat into the stack of materials and exposure of the stack of materials to pressure, the resulting exposure to heat and pressure taking place for a predetermined time period,

none of the solidus temperatures of the plurality of the components being exceeded during the consolidating; and

during the consolidating, the piezoelectric material 3 being directly acoustically coupled to an immediately adjacent component of the front and/or of the rear stack part.

Expressed in other words, a piezoelectric material is provided, as for example a corresponding titanate, tantalate, niobate, orthophosphate or a nitride; that is, a piezo crystal or a piezo ceramic. This material is stacked with the stated joining partners, which may also take the form of a foil, the joining partners being selected from a damping member, a first electrode, a second electrode, the piezoelectric material, and a leader member. On stacking, that is, on arranging the joining partners to form a stack, the following order is preferably maintained:
first electrode and/or damping member,
metallic joining foil,
piezoelectric material,
metallic joining foil,
second electrode and/or leader member.

Subsequently, the stack obtained is exposed to a temperature and optionally to an additional pressing pressure. Exposure to the temperature is also here called temperature exposure, the temperature in particular lying below a solidus temperature of all the components of the metallic joining foil. A component of the metallic joining foil in this context refers to a pure metal—if the joining foil consists only of a metal plus unavoidable impurities accompanying that metal. A component of the metallic joining foil also refers to any other metal or any metal-containing chemical compound which includes one or more metals and is present in the joining foil. Such components typically include an alloy constituent, as for example the constituent of a eutectic alloy, or an intermetallic phase.

During the exposing, an active layer is formed respectively between the damping member and the piezoelectric material or the first electrode and the piezoelectric material and also between the piezoelectric material and the second electrode or the piezoelectric material and the leader member, by virtue of a chemical reaction occurring between one or more components of the relevant joining partner or between one or more components of the metallic joining foils and the piezoelectric material. The active layer is formed typically in the joining partner adjacent to the piezoelectric material, in the contact region with the piezoelectric material. Given corresponding driving with an electrical impulse of suitable frequency and amplitude of the joining partners utilized as electrodes, this active layer ultimately ensures acoustic coupling of a sample under investigation, irrespective of whether the coupling is via an additional coupling agent introduced between the resulting sound transducer and the sample, or takes place on a dry basis/by way of the surrounding atmosphere.

Depending on the materials used for the leader member and for the optional damping member used, it may be possible to do without the use of dedicated electrodes, if the leader member and the damping member are electrically conductive. In this case, the metallic joining foil connects the corresponding member directly to the piezoelectric material, so that damping member and leader member serve as first and second electrodes, respectively.

According to an embodiment, the plurality of the components provided in addition to the piezoelectric material includes at least one of the following: a leader member, a damping member, an electrode 2, 4 and an active element depot, where the active element depot may take the form of the leader member, the form of the damping member, the form of the electrode 2, 4 or the form of a separate foil 1; where the front stack part and the rear stack part each include a component which is configured as an electrode or functions as an electrode; and where the leader member and the damping member independently of one another may functionally be both electrode 2, 4 and active element depot.

According to an embodiment, the front stack part includes the leader member and/or an electrode 2 including an active element depot, and the rear stack part includes an electrode 4, 2 including an active element depot and/or the damping member.

According to one development of the above embodiment, the damping member also functions as an electrode or is configured as an electrode and can be connected to a power source. In this regard it should be noted that the damping member may be not only a metal but also a ceramic.

Examples known to be electrically conductive (metallike ceramics) are ZrC, TiC, WC, TiN, ZrN, TiB₂, ZrB₂, TiO, TiSi₂ and MoSi₂.

According to an embodiment, the acoustic coupling and/or electrical connection between the joining partners includes formation of an active layer by chemical reaction of a first constituent of the piezoelectric material 3 with a second constituent of the active element depot, the active layer including a phase which is not present in, that is, is extraneous to, or which is merely finely dispersed in, the piezoelectric material 3 originally used and the unjoined front stack part, that is, the unconsolidated front stack part, and/or the originally stacked piezoelectric material 3. This phase is likewise not present, or merely finely dispersed, in the originally stacked rear stack part before the consolidating of the stack. In other words: the active layer including the phase comes about only during the consolidating.

According to an embodiment, the active layer is formed in a component which is immediately adjacent to the piezoelectric material 3 and is selected from leader member, damping member, electrode, and active element depot. In particular, the active layer is formed in a contact region of the component immediately adjacent to the piezoelectric material 3 with the piezoelectric material.

According to an embodiment, the front face 3.2 and the rear face 3.1 of the piezoelectric material 3 are aligned in a plane-parallel manner to one another.

According to an embodiment, the front face 3.2 and/or the rear face 3.1 of the piezoelectric material 3 and the respectively immediately adjacent surface of the component of the corresponding front stack part and of the rear stack part have a roughness≤1 μm.

This promotes the diffusion processes on which the formation of the active layer is based, during the method step of exposure to pressure and/or temperature (introduction of heat).

According to an embodiment, the piezoelectric material 3 is selected from: lead zirconium titanate; lead lanthanum zirconium titanate; barium titanate; gallium orthophosphate; lithium tantalate; lithium niobate; lead titanate; lead niobate; a compound of the langasite group, more particularly a lanthanum gallium silicate, aluminum nitride, and bismuth titanate.

According to an embodiment, the active layer accordingly includes a chemical compound selected from: a copper oxide, a copper titanate, a copper niobate, a silver oxide, a silver titanate, a silver niobate, a titanium oxide, and a titanium niobate.

According to an embodiment, the active layer extends substantially over the total extent of a cross-sectional area of the stack that is oriented orthogonally to a stack direction. In other words, at least one of the surfaces of the piezoelectric material that are substantially opposite one another is connected substantially completely via the active layer to the immediately adjacent joining partner.

According to an embodiment, the active element depot serving to form the

active layer is a joining foil 1 and two active layers are formed at the joining foil 1 immediately adjacent to the piezoelectric material 3 when the joining foil 1 is arranged between the piezoelectric material 3 and the leader member.

According to an embodiment, both aforementioned active layers are formed at mutually opposite sides of the joining foil 1.

According to an embodiment, the two active layers differ in a thickness and/or in a chemical composition.

According to a development of the two above embodiments, the leader member includes a steel and the active element depot includes a silver foil. The leader member may also include copper.

According to an embodiment, the leader member includes silver.

According to an embodiment, the active element depot is a foil 1 including copper, titanium, a copper-based alloy, or a silver-based alloy.

According to an embodiment, the aforesaid silver-based alloy includes 63-71% Ag, 26-35% Cu, and 1-5% Ti, and also unavoidable impurities.

According to an embodiment, the active metal depot is an active solder foil.

Advantageously, active solder foils with different specifications are available commercially.

According to an embodiment, the active solder foil includes at least one of aluminum, hafnium, magnesium, nickel, niobium, titanium, vanadium, yttrium, and zirconium.

According to an embodiment, the pressure exerted during the consolidating is 0.1-5 MPa, preferably 0.2-2 MPa.

According to an embodiment, a heating rate employed during the introduction of heat, and/or during the exposing of the stack to the temperature, or during the temperature exposure, and/or during the consolidating of the stack of materials produced, including joining partners and joining foil, is less than or equal to 100 K/h.

This advantageously avoids oxidation of the surface of the leader member before joining is achieved, that is, before the active layer is formed.

According to an embodiment, the temperature of the stack during the consolidating remains≤600° C.

According to an embodiment, beyond attainment of the temperature of the stack of 300° C., the heating rate is adjusted to a level of less than 100 K/h.

According to an embodiment, the joining method described above and additionally further hereinafter is used for producing a sound transducer, a piezo actuator, a ceramic filter, a ceramic resonator, an intermediate frequency filter or a high-temperature sensor including a ceramic bushing.

According to a further embodiment, a sound transducer system is produced by stacking joining partners to be connected, as follows:
first electrode composed of silver;
lithium niobate piezoelectric material;
joining foil, more particularly a silver foil; and
stainless steel leader serving simultaneously as second electrode.

In this example, silver fulfils the function both of an electrode and of a joining foil, that is, of the active element depot for forming the active layer.

According to an embodiment, the joining foil includes a silver-based alloy. More particularly, the silver-based alloy is a eutectic silver-copper alloy. Silver-based here refers to an alloy which, based on the total weight, consists of a predominant fraction of silver with optional further alloy partners (for example, copper and titanium) and with unavoidable extraneous constituents. Accordingly, a copper-based alloy is an alloy which, based on the total weight, consists of a predominant fraction of copper with optional further alloy partners and with unavoidable extraneous constituents.

According to further embodiments, the alloy includes 70-71% Ag, 26-27% Cu and 2.5-3.5% Ti as well as unavoidable extraneous constituents, that is, impurities. As already observed, however, an active layer may be formed even without titanium, both with the silver and with the copper. This means that in the eutectic silver-copper alloy designated here, titanium also does not act as the only active element. Generally speaking, an active element is an element with oxygen affinity.

According to illustrative embodiments, the material of a joining foil includes a copper-tin alloy, more particularly a eutectic copper-tin alloy.

The copper-based alloys, by comparison with silver-based alloys, generally have a higher oxide-forming activity, which may be advantageous for how rapidly and effectively the active layer is formed. However, it may also be a disadvantage in long-term use of a sound transducer joined with the formation of active layers, after a prolonged time, as a result of more rapid degradation of the active compound, for example.

According to a further embodiment, the joining foil includes an alloy including an active element—for example, titanium, zirconium or hafnium.

Adding the stated active elements to the material of the joining foil allows the effectiveness and intensity of the formation of the active layer to be increased still further, which may shorten the operating times.

The operating time is determined substantially by the duration of the hold time after the joining temperature has been attained. Typical hold times are situated in the range from 10 to 20 h, as for example between 12 to 18 h, more particularly 15 h±1 h. The hold time may, for example, be 15 h.

Different alloys differ in their oxygen activity. If a joining foil is less oxygen-active—such as a silver-based joining foil, for example—a longer joining time is required, but advantageously a greater long-term stability is achieved for the resulting sound transducer in high-temperature service.

If the joining time is to be shortened, then, in accordance with the method proposed here, it is possible to use a more active alloy, for example, a copper-based alloy, albeit possibly with a somewhat detrimental effect on the long-term stability and hence on the service life or period of utilization of the resulting sound transducer. The addition of the active elements Ti, Zr or Hf allows the oxygen activity to be increased still further, producing a further shortening of the joining time, but possibly further impairing the long-term stability. Depending on the particular evaluation criterion—for example, acceptable cost and complexity for production or service life (maximum lifetime), the skilled person is therefore able to achieve the optimum for the particular application at acceptable cost and complexity.

Through the selected active element, advantageously, it is possible to achieve the oxygen activity of the joining foil and hence the shortening of the joining time for the use of the joining foil, as proposed here, in combination with the silver-based or copper-based alloy of the joining foil.

According to an embodiment of a production method for a sound transducer system including a steel leader member, composed more particularly of a stainless steel, the heating rate during the consolidating, that is, during the exposure of the stack of materials produced to the temperature, below a temperature of 300° C. is more than 100 K/h.

Advantageously, this enables an accelerated joining operation while at the same time preventing oxidation, since stainless steel starts to oxidize only beyond 300° C.

According to an embodiment, the piezoelectric material is selected from: lead zirconium titanate; barium titanate; gallium orthophosphate; lithium tantalate; lithium niobate; lead titanate; lead niobate; a lanthanum gallium silicate (referred to as langasite), aluminum nitride, and bismuth titanate.

Advantageously, this enables adaptation to the coefficient of thermal expansion of the leader member used and to the particular desired upper limit on the service temperature of the sound transducer system.

According to an embodiment, a material of the metallic electrode is selected from: Ag, Cu and Ti alloys.

Advantageously, this embodiment enables the electrode to be utilized as a joining foil, that is, as an active element depot.

According to a further embodiment, a proposal is made to use a joining layer for producing a high-temperature-resistant connection between a leader member and a piezoelectric material, the joining layer being selected from: a silver-based alloy, a copper-based alloy and a metallic joining foil, and the alloys each including an active metal selected from titanium, zirconium and hafnium.

This use enables the advantages already described above.

The embodiments described above may be combined with one another as desired.

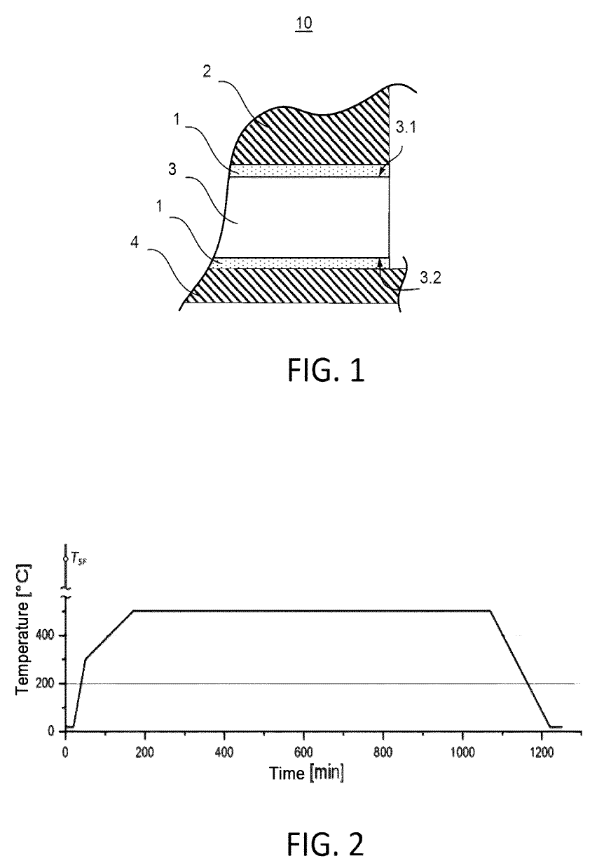

Represented schematically in FIG. 1 is the arrangement 10 utilized in the disclosure for joining the piezoelectric material for an embodiment. It includes a piezoelectric material 3 which is brought into substance-to-substance contact with a respective electrode—an inner electrode 2 and an outer electrode 4—at two sides 3.1, 3.2 opposite one another, in each case via a joining foil 1.

A joining foil 1 utilizable in the disclosure is based, for example, on a eutectic Ag—Cu alloy with an addition of 3% titanium as active component. Subsequent investigations have shown that adding an additional active component such as titanium, for example, is not mandatory, meaning that further alloys, both silver-based and copper-based alloys, and also pure silver and copper foils are also suitable as joining foils employable in the disclosure.

The individual components of the arrangement shown schematically in FIG. 1 are joined by being pressed against one another in a clamping apparatus with a defined pressing force, so as to ensure effective mechanical contact between piezoelectric material, active solder foil, and electrodes.

The joining operation proposed in the disclosure takes place advantageously in accordance with the temperature profile represented in FIG. 2. The temperature profile is controlled specifically during the joining operation. In particular, a temperature increase per unit time (heating rate) is adjusted such that there is no premature formation, at the surface of the metallic electrode, of any intrinsic oxides, which can adversely affect subsequent formation of an active layer in the contact area.

The formation of an active layer and hence the sustained acoustic connection (coupling) commence at low rates beyond just around 400° C. and accelerate as the temperature increases, and so the heat treatment at a final joining temperature of 500° C. ensures the formation of a surface-covering active compound between the piezoelectric material and the joining foil and an effective transmission of ultrasound with long-term stability.

If using ferrous electrodes or leader materials, it must be ensured that beyond 300° C. the heating rate does not exceed 100° C./h, in order to prevent unwanted irony oxides forming in the boundary layer between the joining foil 1 and the electrodes 2, 4.

The temperature profile indicated in FIG. 2 applies to a stack of materials composed of steel electrodes, lithium niobate as piezo crystal, and active element depot in the form of a joining foil composed of a eutectic Ag—Cu alloy with addition of 3% titanium. In the general case, the parameters of the joining operation are application-specific and are selected to take account of the properties not only of the components of the metallic joining foil but also of the respective joining partners.

The joining temperature on the one hand must lie within the limits of thermal stability of the joining partners, but on the other hand must be kept as high as possible in order to enable sufficiently rapid formation of active layer at the joining material, as it is this speed that determines the minimal holding time and hence the rapidity of the joining operation. A compressive force introduced into the stack of materials, via a clamping device, for example, may accelerate the joining operation to some degree, but of course must not exceed the degree to which the joined materials can be subjected to mechanical stress (the brittleness of the piezoelectric material being a particular factor).

The product of the above chemical reaction, between the joining material and the joining partner, both of which are in a solid state, without any interim liquification of any components, forms the so-called active layer, which, with the attainment of virtually cavity-free filling of the space between the adjacent joining partners, ensures comprehensive, sound-transmitting coupling.

When the stack of the stated joining partners and metallic joining foils is exposed to a temperature, a certain rate of increase must not be exceeded. A maximum rate of temperature increase that has proven favorable for various combinations of joining partners and metallic joining foils is 100° C./h.

In the context of joining a piezoelectric ceramic, as also in the later application of the sound transducer achieved with the configuration of at least one active layer, the temperature used is advantageously not to reach the Curie temperature of a piezo ceramic. Conversely, when using a sound transducer whose piezoelectric material has a crystalline structure, such as lithium niobate, the Curie temperature certainly can be exceeded. Since the joining operation proposed in the disclosure does not entail melting, a higher service temperature of a sound transducer including a piezo crystal may indeed lower the long-term stability of the sound transducer, but may also in principle be above the joining temperature.

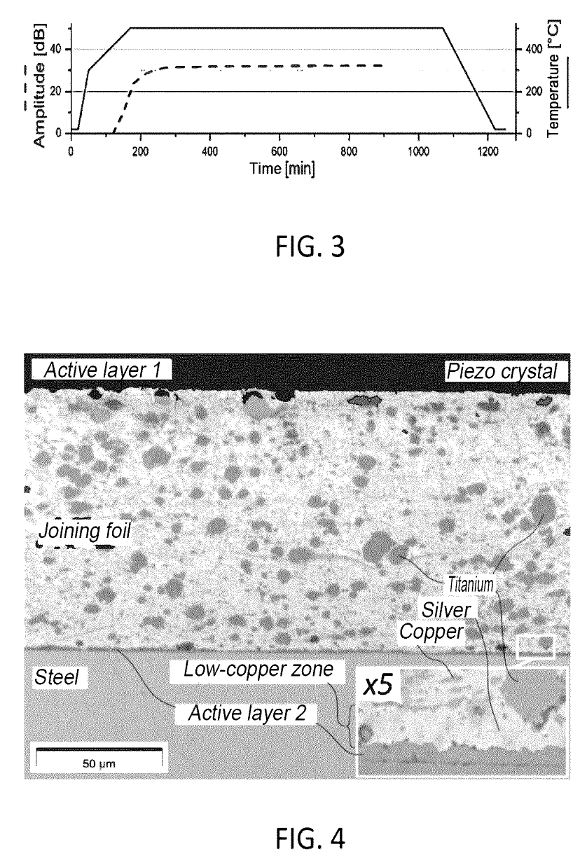

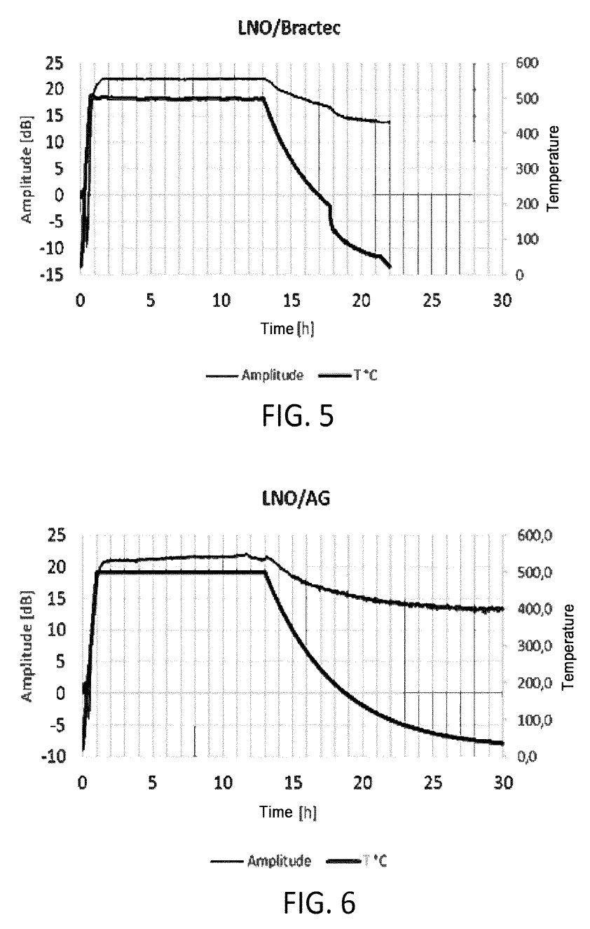

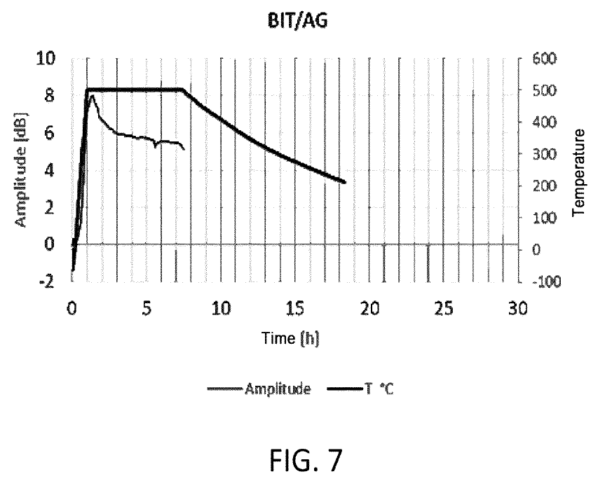

The pressing pressure exerted when the stack of the joining partners is exposed to pressure influences the joining time needed for the active layer to form. The required joining time is in inverse proportion to the pressing pressure applied. By increasing the pressing pressure, therefore, it is possible to accelerate the operating speed or reduce the joining time required. On application of a pressing force of 100 N on a combination of steel electrodes, lithium niobate as piezo crystal (thickness 1.83 mm, diameter 20 mm) and joining foils composed of a eutectic Ag—Cu alloy with addition of 3% titanium (foil thickness 100 μm), with a resulting pressing pressure of 0.3 MPa, it is possible to obtain effective acoustic coupling after 15 hours' joining time at 500° C. The acoustic coupling was characterized by evaluating the amplitude of a continuous ultrasound signal (see FIG. 3). For the joining of lithium niobate as piezo crystal onto a steel leader member with silver foil electrodes on either side, effective acoustic coupling was achieved with a pressing force of 400 N in a joining time of 12 h (cf. FIG. 6). The dimensions of the piezo crystal were 10×20 mm, the pressing pressure therefore being 2 MPa. Under identical conditions, effective acoustic coupling was also achieved with bismuth titanate as piezo ceramic on a steel leader member with silver foil electrodes arranged on the piezoelectric material on either side (cf. FIG. 7). Effective acoustic coupling here refers to a force-fitting connection which permits reliable transmission of acoustic vibrations in the range of 10 kHz-10 MHz, more particularly of 50 kHz-5 MHz, as for example of 100 kHz-4 MHz.

For the reliable formation of an active layer and thus for successful joining, the joining faces advantageously have a defined surface quality. The joining faces of the piezoelectric material are preferably configured in a plane-parallel manner to one another and polished to a roughness of less than one micrometer.

The use of a joining foil is optional, dependent on the leader member used (for example, copper). In other words, when using a copper leader member, the copper in the stack of materials serves as a depot of the active element (as a joining foil, so to speak) for forming the active layer, and also fulfills the electrode function. If, therefore, the piezo crystal is placed directly onto the copper leader member and tightened with a pressing force, an active layer may be formed between the two at 500° C. and hence an active compound (active layer) and acoustic coupling may be formed without a joining foil. If the material of the leader member (a) is conducting and (b) forms an active layer in contact with the piezoelectric resonator used, during the joining process, it is possible to do without the use of a separate joining foil.

FIG. 4 shows a metallographic picture of a joining layer, produced illustratively, in the joining of a lithium niobate piezo crystal with a steel electrode via a joining foil composed of a eutectic Ag—Cu alloy containing 3% by mass titanium, after 15 hours' joining time at 500° C. Although this joining temperature is around 180° C. below the solidus temperature of the joining material, it is clearly evident that an active layer has been formed on either side of the foil, and thus a chemical reaction has taken place between adjacent components. According to the theory, the active layer contains substantially titanium oxide. However, subsequent experiments have shown that titanium-free foils composed both of pure copper and of pure silver as joining material also lead to the formation of active layers on either side and ensure a comparable joining quality. This demonstrates that copper and silver as elements also each form an active layer and are therefore possibly likewise present in the active layer depicted. This is also suggested by the phase distribution of the components in the joining foil after the joining operation has taken place: while the middle region of the foil is virtually no different from an original phase distribution in the foil used, the regions immediately adjacent to the active layers contain substantially less copper or even none.

The joining principle developed results, in comparison to the existing high-temperature-resistant coupling technique using liquid glass (EP 0 459 431 B1), in a substantially higher long-term temperature stability; it does not require costly and inconvenient protective measures to counter corrosive attack, as would be needed in the case of a glass melt; and it also allows the bonding partners, once joined, to be used at low temperatures as well, whereas the coupling via a glass melt (glass coupling) can be used only above the softening temperature of the glass, beyond around 350° C.

Aspects of the present disclosure may be described in a supplementary manner in accordance with the points below:

production of an active joined connection via a joining foil at a temperature well below the melting point of the joining foil (solder melting point) or its solidus temperature if a melting interval is present;

joining method for joining a piezoelectric material onto a sound leader member via a joining layer formed during joining, this layer being referred to here as active layer;

construction of a stack of materials as described in the disclosure;

sound transducer system based on the joining technique described;

sound transducer system with angular insonification based on the joining technique described;

sound transducer system for flow measurement based on the joining technique described;

multiple sound transducer system for flow measurement based on the joining technique described.

Joining method for producing a sound transducer system (10) for extreme-temperature service, including:

providing a piezoelectric material (3) including two surfaces (4.1, 4.2) opposite one another and plane-parallel to one another;

providing two metallic electrodes (2, 4), with at least one of the two electrodes containing Fe;

arranging a respective joining foil (1) between one of the two surfaces (3.1, 3.2) opposite one another and one of the two metallic electrodes (2, 4), so that the two surfaces (3.1, 3.2), opposite one another, of the piezoelectric material (3) are covered over their area with the respective joining foil (1);

where the joining foil includes an active solder including a copper-based alloy including an active metal, a silver-based alloy including an active metal, a nickel-based alloy and an active metal, or a gold-based alloy and an active metal, the active metal being selected from Ti, Hf, Zr, Cr, Y, Nb and/or V;

exposing a stack of materials, obtained on arranging the joining foils between the electrodes and the piezoelectric material, to a pressing pressure of 0.1-5 MPa, preferably 0.2-2 MPa, the exposure being maintained over a total duration of the consolidating;

heating the stack of materials according to a temperature profile of its maximum temperature below a solidus temperature of each metallic constituent of the joining foil (1), where optionally the maximum temperature on heating of the stack of materials is 500° C.;

where the maximum temperature is held at least over a time period of 1 hour, so that active layers are formed at the interfaces between the electrodes and the joining foil and also between the joining foil and the piezoelectric material through a chemical reaction between components of the joining material and the joining partners, with these active layers—in terms of materials science characteristics—each including a new phase which was not present, or was present only dispersely, in the joining foil beforehand.

Joining method according to the preceding aspect, wherein the time period of the joining (joining time) may be reduced under certain conditions (high pressing pressure, high chemical activity of the joining partner-joining material combination, surface quality, that is, form-fitting contact of adjacent surfaces).

Joining method according to any of the preceding aspects, wherein the joining foil (1) either is a pure metal foil (silver foil, copper foil, titanium foil) or includes an active solder, the active solder including an alloy including at least two of Ag, Cu, Sn, Zn and/or In, and an active metal, particularly Ti, Zr, Hf, Cr, Y, Nb and/or V.

Joining method according to the preceding aspect, wherein the joining foil is a single material which includes one or more metals which on heating, in simultaneous surface contact with a joining partner, selected from piezoelectric material (3), leader member and electrode, react chemically with one or more elements of the joining partner, with the product of this reaction being an active layer which forms in the immediate region of contact of the joining partners and which makes a substance-to-substance attachment of the joining partners to the joining foil.

The present disclosure has been explained using general explanations, aspects, embodiments and practical working examples. These working examples should not by any means be understood as limiting on the present disclosure.

It is understood that the foregoing description is that of the preferred embodiments of the invention and that various changes and modifications may be made thereto without departing from the spirit and scope of the invention as defined in the appended claims.

### REFERENCE SIGNS

1 foil, joining foil, active solder foil

2 damping member and/or inner electrode

3 piezoelectric material

3.1, 3.2 mutually opposite surfaces of the piezoelectric material

4 leader member and/or outer electrode

10 stack, joining arrangement (detail)

1. A joining method for producing a sound transducer system, the method comprising:
providing a piezoelectric material and a plurality of components, each of the components having a solidus temperature;
arranging the piezoelectric material and the plurality of the components in a stack, so that adjacent to a front face of the piezoelectric material there is a front stack part and adjacent to a rear face of the piezoelectric material there is a rear stack part;
consolidating the stack using heat and pressure for a predetermined time period, wherein none of the solidus temperatures of the plurality of the components is exceeded; and,
during said consolidating, the piezoelectric material being directly acoustically coupled to an immediately adjacent component of at least one of the front and rear stack part.

2. The joining method of claim 1, wherein the plurality of components includes at least one of: a leader member, a damping member, an electrode, and an active element depot; and, the front stack part and the rear stack part each include one of said plurality of components configured as an electrode.

3. The joining method of claim 2, wherein the active element depot is in a form of the leader member, the damping member, the electrode, or a separate foil.

4. The joining method of claim 2, wherein at least one of the leader member and the damping member, independently, is functionally both electrode and active element depot.

5. The joining method of claim 2, wherein the front stack part includes at least one of the leader member and an electrode having an active element depot; and, the rear stack part includes an electrode having at least one of an active element depot and the damping member.

6. The joining method of claim 5, wherein the damping member is also configured as an electrode.

7. The joining method of claim 1, wherein at least one of the acoustic coupling and an electrical connecting includes formation of an active layer by chemical reaction of a first constituent of the piezoelectric material with a second constituent of an active element depot, comprising a phase which is extraneous to or merely finely dispersed in the piezoelectric material originally used and at least one of the unjoined front stack part and the piezoelectric material originally used and the unjoined rear stack part.

8. The joining method of claim 7, wherein the active layer is formed in one of said plurality of components immediately adjacent to the piezoelectric material and is selected from leader member, damping member, electrode, and the active element depot; and, the active layer is formed in a contact region of the one of the plurality of components immediately adjacent to the piezoelectric material with the piezoelectric material.

9. The joining method of claim 1, wherein the front face and the rear face of the piezoelectric material are aligned in a plane-parallel manner to one another.

10. The joining method of claim 1, wherein at least one of the front face and the rear face of the piezoelectric material and the respectively immediately adjacent surface of the component of the front stack part and of the rear stack part have a roughness≤1 μm.

11. The joining method of claim 1, where the piezoelectric material is selected from: lead zirconium titanate; lead lanthanum zirconium titanate; barium titanate; gallium orthophosphate; lithium tantalate; lithium niobate; lead titanate; lead niobate; a compound of the langasite group, more particularly a lanthanum gallium silicate, aluminum nitride, and bismuth titanate.

12. The joining method of claim 7, where the active layer comprises a chemical compound selected from: a copper oxide, a copper titanate, a copper niobate, a silver oxide, a silver titanate, a silver niobate, a titanium oxide, and a titanium niobate.

13. The joining method of claim 12, where the active layer includes a total extent of a cross-sectional area of the stack that is aligned orthogonally to a stack direction.

14. The joining method of claim 12, wherein the active element depot is a joining foil and two active layers are formed at the joining foil immediately adjacent to the piezoelectric material when the joining foil is arranged between the piezoelectric material and the leader member.

15. The joining method of claim 14, where the two active layers are formed at mutually opposite sides of the joining foil.

16. The joining method of claim 14, wherein the two active layers differ in at least one of a thickness and a chemical composition.

17. The joining method of claim 2, wherein the leader member comprises a steel and the active element depot comprises a silver foil, or the leader member comprises copper.

18. The joining method of claim 2, wherein the leader member comprises silver.

19. The joining method of claim 2, wherein the active element depot has a foil including copper, titanium, a copper-based alloy, or a silver-based alloy.

20. The joining method of claim 19, wherein the silver-based alloy comprises 63-71% Ag, 26-35% Cu, and 1-5% Ti, and also unavoidable impurities.

21. The joining method of claim 2, wherein the active element depot is an active solder foil.

22. The joining method of claim 21, wherein the active solder foil includes at least one of aluminum, hafnium, magnesium, nickel, niobium, titanium, vanadium, yttrium, and zirconium.

23. The joining method of claim 1, wherein the pressure exerted during the consolidating is 0.1 MPa to 5 MPa.

24. The joining method of claim 1, wherein a heating rate during the consolidating is ≤100 K/h.

25. The joining method of claim 1, wherein a temperature of the stack during the consolidating is 600° C.

26. The joining method of claim 25, wherein a heating rate beyond attainment of the temperature of the stack of 300° C. is less than 100 K/h.

27. The joining method of claim 1, wherein the pressure exerted during the consolidating is 0.2 MPa to 2 MPa.

28. A method for producing a sound transducer, a piezo actuator, a ceramic filter, a ceramic resonator, an intermediate frequency filter or a high-temperature sensor comprising a ceramic bushing via the joining method of claim 1.
